(19) United States
(12) Patent Application Publication
(10) Pub. No.: US 2008/0031073 A1
(43) Pub. Date: Feb. 7, 2008

(54) Memory Module and Method for Operating the Same

(75) Inventor: Ulrich Brandt, Munchen (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/832,264

(22) Filed: Aug. 1, 2007

(30) Foreign Application Priority Data
Aug. 7, 2006 (DE) 102006036822.3

(51) Int. Cl. G11C 5/14

(52) U.S. Cl. 365/229

(57) ABSTRACT

A memory module includes module-internal command/address bus lines that are terminated on the memory module by terminating resistors and a terminating voltage. The memory module also includes switches to disconnect the terminating resistors during quiescent states of the memory module in which no activity by the memory module is expected. Therefore, power consumption of the memory module is considerably reduced during the quiescent state.

### CROSS REFERENCE TO RELATED APPLICATIONS

This application claims priority under 35 U.S.C. §119 to Application No. DE 102006036822.3 filed on Aug. 7, 2006, entitled “Method for Operating a Memory Module, and Memory Module,” the entire contents of which are hereby incorporated by reference.

### BACKGROUND

In order to avoid signal reflections, command/address bus lines which are used to control memory chips are connected, via a terminating resistor, to a terminating voltage and are thus terminated. In the case of memory modules based on the DDR (double data rate) standard, the command/address bus lines as well as the data bus lines are terminated on the main board (“motherboard”). In the case of the DDR2 (double data rate 2) standard, the data bus lines are terminated in the individual memory chip, which is referred to as “on-die termination” (ODT), while the command/address bus lines are terminated on the main board.

In the case of the DDR3 standard, the data bus lines are terminated in the memory chip using on-die termination, while the command/address bus lines are terminated on the memory module, which is referred to as “on-DIMM termination,” “DIMM” standing for “dual inline memory module.” This termination on the memory module consumes power with a signal-dependent current even in the case in which an active signal is not applied to the command/address bus lines. During stand-by times in a quiescent state of the memory module (active power down, pre-charge power down or self-refresh), this current is added to the stand-by current required by the memory module.

### SUMMARY

A memory module and a method for operating a memory module are described herein. The memory module includes a plurality of memory chips which are connected to module-internal command/address bus lines that are terminated on the memory module by respective terminating resistors and a terminating voltage. The memory module also includes switches to disconnect the terminating resistors during quiescent states of the memory module in which no activity by the memory module is expected. Therefore, power consumption of the memory module is considerably reduced during the quiescent state. The memory module further comprises interface connections configured to connect to external command/address bus lines. The method for operating a memory module includes controlling the switches to connect and to disconnect the terminating resistors on the memory module from the module-internal command/address bus lines.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The memory module and method are explained in more detail with reference to the figures, where:

FIG. 1 shows a schematic circuit according to an exemplary embodiment with connected terminating resistors for the command/address bus;

FIG. 2 shows a schematic circuit for terminating the buses in the DDR standard;

FIG. 3 shows a schematic circuit for terminating the buses in the DDR2 standard; and

FIG. 4 shows a schematic circuit for terminating the buses in the DDR3 standard according to the prior art.

### DETAILED DESCRIPTION

The following describes a memory module having low power consumption and a method for operating a memory module.

The method comprises the following steps. In the event of an operating state of the memory module changing into a quiescent state, the terminating resistors are disconnected from the command/address bus lines. In these phases, it is not necessary to terminate the command/address bus lines. As a result, the stand-by current during the quiescent state can be significantly reduced.

The method includes dynamically disconnecting the respective terminating resistors from the command/address bus lines and connecting to the latter again on the basis of the operating state of the memory module.

One simple possible way of determining the operating state of a memory module is to evaluate the clock enable (CKE) signal which indicates whether the clock signal is intended to be assessed for the memory chips and whether the memory chips are intended to carry out an operation.

The memory module includes switches to connect and disconnect the terminating resistors. Optionally, the switches may comprise field effect transistors which result in particularly rapid connection and disconnection of the terminating resistors.

The memory module may be configured such that the switches are controlled via a memory module control device. The control device switches the switches on and off to disconnect the terminating resistor from the internal command/address bus lines.

A particularly rapid configuration of the switches is provided by virtue of the switches being in the form of field effect transistors (FET).

As a result of the fact that a module-internal clock enable line is used in the in the exemplary embodiment, the level of the line indicating whether the memory module is in a quiescent state or in an active state and indicating whether the memory module should switch to the respective state, data which is already present and relates to the operating state of the memory module may be used in a simple manner to control the switches. For this purpose, the DDR, DDR2 and DDR3 standards define that a high level (“high”) on the clock enable line describes an active state of the memory chips, in which clock signals are intended to be assessed, and that a low level (“low”) indicates a power-saving mode during which the memory chips do not carry out an operation.

One embodiment of the memory module that the field effect transistors are normally-off field effect transistors and that the gates of the field effect transistors are connected to a CKE (clock enable) line, as a result of which the respective gate of the field effect transistors turns on in the event of a “high” signal level on the CKE line and thus connects the terminating resistors to the command/address bus lines. In the event of a “low” signal on the CKE line, the field effect transistors are in the off state and thus disconnect the terminating resistors from the command/address bus lines.

In the following paragraphs, exemplary embodiments of the memory module and the method are described in connection with the figures.

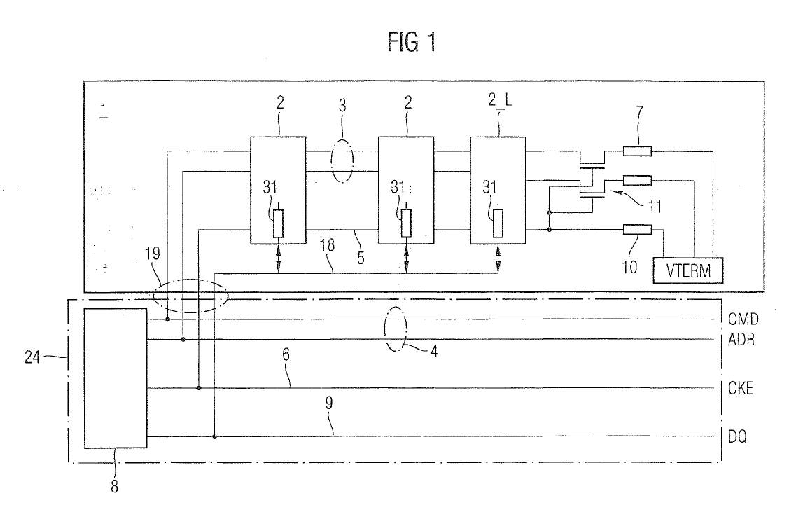

FIG. 1 schematically illustrates a memory module 1 (DIMM) on which a plurality of memory chips 2 (three in the example illustrated but often eight, sixteen or thirty two) are mounted. The memory module 1 is connected, via connections 19 (e.g., interface connections), to a main board 24 (e.g., “motherboard”), only part of which is illustrated here. A memory module control device 8 (i.e., memory module controller) as well as one or more microprocessors, input modules, output modules etc. (not illustrated here), which are connected to one another via a bus system, are situated on the main board 24, for example. In this case, the bus system comprises, inter alia, external command/address bus lines 4 (CMD, ADR) for transmitting commands and memory addresses (only two command/address bus lines 4 are illustrated for example in FIG. 1; depending on the bit width of the command/address bus, there are twenty command/address bus lines in the case of a command/address bus having a width of 20 bits, for example), a data bus 9 (DQ) for transmitting data and an external clock enable line 6 (CKE). The external clock enable line 6 is used to control quiescent states of the memory module 1 via the memory module control device 8. The data bus 9 (DQ) includes a plurality of data bus lines (not illustrated), (e.g., 64 data bus lines for a data bus 9 with a width of 64 bits).

The memory chips 2 are provided with commands and addresses via module-internal command/address bus lines 3 which are connected to the external command/address bus lines 4 via the connections 19. A module-internal data bus 18 has, for example, 64 data bus lines (not individually illustrated) which are connected to the memory chips 2 in blocks. In the case of, for example, a data bus having a width of 64 bits and comprising 64 data bus lines and in the case of eight memory chips 2 on the memory module 1, eight data bus lines are respectively connected to the individual memory chips 2 in order to write data to the memory chips 2 or read data from the memory chips 2. For this purpose, the module-internal data bus 18 is connected to the external data bus 9 via the connections 19.

The memory module 1 is controlled via the memory module control device 8 which is connected to: the external command/address bus lines 4, to the data bus 9 and to the external clock enable line 6. The memory module control device 8 is generally on the main board 24, as illustrated here, but exemplary embodiments in which the memory module control device 8 is arranged on the memory module 1 are also conceivable. In this case, the described method can be used accordingly and the described memory module can be adapted accordingly.

In accordance with the specification for DDR2 and DDR3, the module-internal data bus lines 18 are terminated via data bus terminating resistors 31 which are in the memory chips (“dies”) 2 (i.e., “on-die termination”). The module-internal command/address bus lines 3 are respectively connected, via terminating resistors 7, to a terminating voltage VTERM which ensures that interfering signal reflections do not occur, as is provided for in the specification for DDR3.

The module-internal clock enable line 5 is connected to an external clock enable line 6 via the connections 19; the CKE signal is supplied to the memory module 1 in this manner. The module-internal clock enable line 5 has a high signal level in the active state of the memory module 1 and a low signal level in the quiescent state of the memory module 1. The module-internal clock enable line 5 is likewise connected to the terminating voltage VTERM via a clock enable terminating resistor 10 and is thus terminated. The source and drain connections of a respective field effect transistor 11 are interposed between the last memory chip 2_L and the terminating resistor 7 on the module-internal command/address bus lines 3. The gates of the field effect transistors 11 are connected to one another and to the module-internal clock enable line 5.

If the field effect transistors 11 are in the form of normally-off field effect transistors, the terminating resistors 7 are connected to the command/address bus lines 3 in the event of a “high” clock enable signal and are disconnected from the command/address bus lines 3 in the event of a “low” clock enable signal. This leads to a significant current reduction in the quiescent state (“stand-by mode”) of the memory module 1, which is distinguished by a “low” signal on the internal clock enable line 5. In this case, a “pre-charge power down mode,” an “active power down mode” or a “self-refresh mode” can be envisaged as the quiescent state. All memory banks are closed in the “pre-charge power down mode,” whereas one memory bank remains open in the “active power down mode.”

If, in contrast, the “low” and “high” signals are internally interchanged in order to operate the module-internal clock enable line 5, the corresponding effect can be achieved using “normally-on” field effect transistors.

In the exemplary embodiment illustrated, separate switches 11 are provided for each module-internal command/address bus line 3 and its terminating resistors 7. It is also possible to switch all of the terminating resistors via one switch which should then preferably be arranged between the terminating resistors 7 and the terminating voltage VTERM.

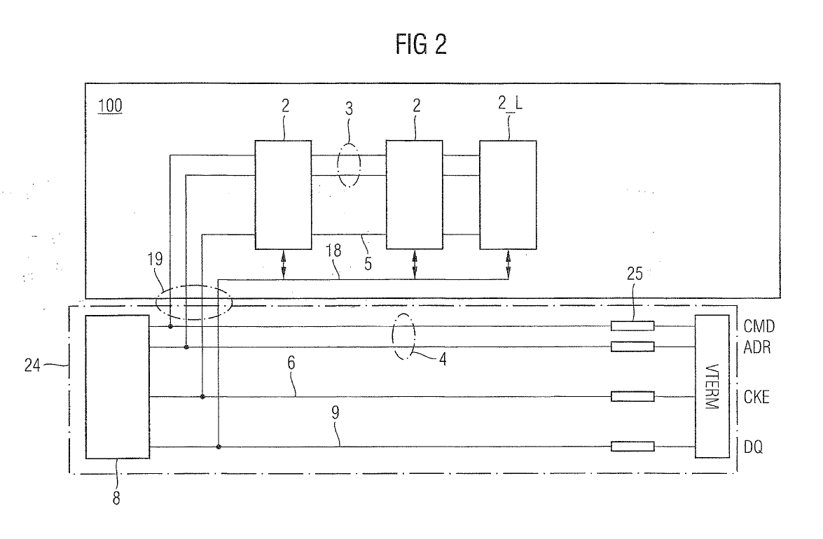

FIG. 2 illustrates, as the prior art, the manner in which the external command/address bus lines 4 are terminated on the main board 24 via terminating resistors 25 and the terminating voltage VTERM in the case of a memory module 100 based on the DDR standard.

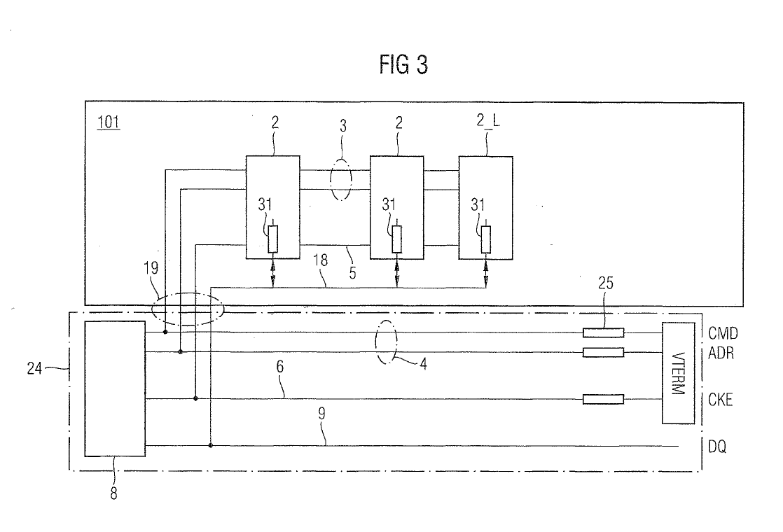

FIG. 3 illustrates the manner in which the external command/address bus lines 4 are terminated on the main board 24 via terminating resistors 25, while the internal data bus lines 18 are terminated in the memory chip 2 (“on-die termination (ODT)”) via terminating resistors 31 in the case of a memory module 101 based on the DDR2 standard.

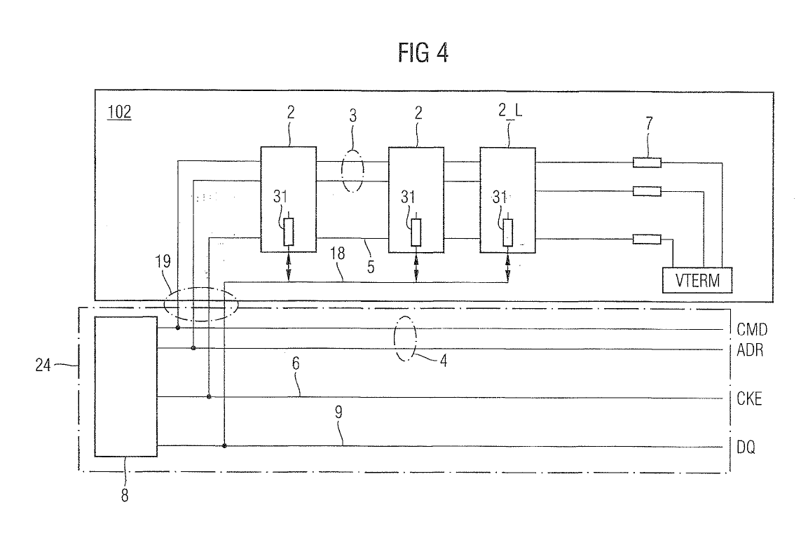

FIG. 4 schematically shows a conventional memory module 102 based on the DDR3 standard, the memory module comprising terminating resistors 7 for the internal command/address bus lines 3 without the terminating resistors 7 being able to be disconnected from the internal command/address bus lines 3 in the quiescent state. As a result, such a memory module 102 also draws a high current in the quiescent state.

The described method and the described memory module can thus be used to ensure that only a reduced stand-by current flows in the quiescent states of the memory module, thus resulting in a power saving and, in addition, also in less evolution of heat as a result.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A method for operating a memory module with a plurality of memory chips connected to respective terminating resistors on the memory module via module-internal command/address bus lines, the method comprising:
disconnecting the respective terminating resistors from the module-internal command/address bus lines, in response to an operating state of the memory module changing to a quiescent state.

2. The method according to claim 1, further comprising:
connecting the respective terminating resistors to the module-internal command/address bus lines, in response to an operating state of the memory module changing to an active state.

3. The method according to claim 2, wherein the connection and disconnection of the terminating resistors is controlled via a clock enable signal.

4. The method according to claim 2, wherein the memory module further comprises a plurality of field effect transistors, the connection and disconnection of the terminating resistors being controlled via the field effect transistors.

5. The method according to claim 1, further comprising:
dynamically disconnecting the terminating resistors from and connecting the terminating resistors to the module-internal command/address bus lines, in response to an operating state of the memory module changing to a quiescent state and subsequently changing to an active state.

6. The method according to claim 1, wherein the disconnection of the terminating resistors is controlled via a clock enable signal.

7. The method according to claim 1, wherein the memory module further comprises a plurality of field effect transistors, the disconnection of the terminating resistors being controlled via the field effect transistors.

8. A memory module, comprising:
a plurality of memory chips;
a plurality of interface connections configured to connect to external command/address bus lines;
module-internal command/address bus lines connected to the memory chips and to the interface connections;
a plurality of terminating resistors respectively connected to the module-internal command/address bus lines; and
a plurality of switches respectively connected between the module-internal command/address bus lines and the terminating resistors, the switches being configured to connect and disconnect the terminating resistors from the module-internal command/address bus lines.

9. The memory module according to claim 8, wherein the switches are responsive to a memory module control device connected to the interface connections, the switches being configured to switch on and off.

10. The memory module according to claim 8, further comprising:
a memory module control device;
wherein the switches are responsive to the memory module control device, the switches being configured to switch on and off.

11. The memory module according to claim 8, wherein the switches each comprise a field effect transistor.

12. The memory module according to claim 11, further comprising:
a module-internal clock enable line connecting the field effect transistors to an external clock enable line.

13. The memory module according to claim 12, wherein the field effect transistors are normally-off field effect transistors with gate terminals connected to the module-internal clock enable line.

14. The memory module according to claim 8, further comprising:
a module-internal clock enable line connecting the switches to an external clock enable line.
